(19) United States
(12) Patent Application Publication
(10) Pub. No.: US 2007/0193507 A1
(43) Pub. Date: Aug. 23, 2007

(54) Radiation detector

(75) Inventors: Csaba Szeles, Allison Park, PA (US); Honnavalli R. Vydyanath, Huntington Beach, CA (US)

Correspondence Address: THE WEBB LAW FIRM, P.C., 700 KOPPERS BUILDING, 436 SEVENTH AVENUE, PITTSBURGH, PA, 15219, US

(73) Assignee: II-VI INCORPORATED, Saxonburg, PA (US)

(21) Appl. No.: 10/578,057

(22) PCT Filed: Nov. 10, 2003
(86) PCT No.: PCT/US03/35726

§ 371 Date: Mar. 19, 2007

(51) Int. Cl. C30B 29/46; C30B 21/04; C30B 13/00

(52) U.S. Cl. 117/956; 117/43; 117/45

(57) ABSTRACT

A radiation detector made from a compound, or alloy, comprising CdxZn1-xTe (0≦x≦1), an element from column III or column VII of the periodic table in a concentration about 10 to 10,000 atomic parts per billion and an element selected from C the group consisting of La, Ce, Pr, Nd, Pm, Sm, Eu, Gd, Tb, Dy, Ho, Er, Tm, Yb and Lu in a concentration about 10 to 10,000 atomic parts per billion exhibits full electrical compensation, high-resistivity, full depletion under an applied electrical bias and excellent charge transport.

### BACKGROUND OF THE INVENTION

1. Field of the Invention

The present invention relates to radiation detectors and a method of making the same. More specifically, the present invention is a fundamentally new approach for growing semi-insulating CdₓZn₁₋ₓTe (0≦x≦1) crystals with full active volume for detecting radiation in the 1 keV-5 MeV photon energy range.

2. Description of Related Art

Fundamental physical properties govern the selection of material for all radiation detector applications. Firstly, the material must exhibit high electrical resistivity. Secondly, the material must exhibit an excellent transport of the charge carriers generated by external radiation. Lastly, the material must allow an applied electric field to extend through the whole volume of the crystal, i.e., full depletion. None of these properties is exhibited in high-purity, intrinsic or undoped Cadmium Telluride, Zinc Telluride or Cadmium Zinc Telluride, i.e., CdₓZn₁₋ₓTe (0≦x≦1), grown by any known method. The 0≦x≦1 concentration or mole fraction range encompasses Cadmium Zinc Telluride (CdZnTe) with any Zn percentage including Cadmium Telluride CdTe (x=1) and ZnTe (x=0).

High-purity intrinsic CdₓZn₁₋ₓTe (0≦x≦1) typically has low electrical resistivity due to the formation of a large density of intrinsic or native defects, notably cadmium (Cd) vacancies in tellurium (Te) rich growth conditions or Cd interstitials in Cd rich growth conditions. In addition, an intrinsic defect of unknown origin with a deep level at the middle of the band gap is formed in large concentrations. This intrinsic defect has electronic properties that do not permit full depletion of the device when the defect is present in large concentrations.

High resistivity CdₓZn₁₋ₓTe (0≦x≦1) is typically obtained by doping with column III elements, e.g., In, Al and Ga, in a vertical or horizontal Bridgman process or with column VII elements, e.g., Cl, in the travelling heater method. In these processes, however, significant concentrations of dopants are typically introduced that lead to diminished carrier transport and secondary effects, such as polarization of the detectors. This latter phenomenon refers to the reduction of the effective volume, i.e., efficiency, due to the collapse of the internal electric field due to carrier trapping caused by the introduced dopants or other defects. With the foregoing doping scheme it is also difficult to technologically control the achieved resistivity due to incomplete electrical compensation. As a result, electrical resistivity variation in the 1×10⁶-1×10⁹ Ohm-cm range is typically observed.

Electrical compensation by dopants introducing energy levels to the middle of the band gap is often used in column III-V compounds to obtain semi-insulating material. However, none of these doping schemes has solved the problem of passivating intrinsic defects forming in these materials. Examples include, but are not limited to, iron (Fe) doping in indium-phosphide (InP) and chromium (Cr) doping in gallium arsenide (GaAs). The intrinsic defect was identified as a native defect EL2 in gallium arsenide (GaAs). The addition of a single doping element with a deep level in the middle of the band gap in high concentration introduces a strong trapping of charge carriers produced by external radiation and does not passivate the intrinsic deep level that causes incomplete depletion of the devices. As a result, radiation detectors fabricated from so produced semi-insulating column III-V compounds, e.g., GaAs, are hampered by low resistivity and limited active depletion regions and do not allow for passivation of the intrinsic defects.

Incorporation of unknown impurities and the formation of native defects can render intrinsic CdₓZn₁₋ₓTe (0≦x≦1) highly-resistive. However, such material typically exhibits strong carrier trapping whereupon the performance of the radiation detector is compromised. When impurities, native defects and their associations are incorporated in an uncontrolled manner the properties of the CdₓZn₁₋ₓTe (0≦x≦1) ingots vary from growth to growth and exhibit strong spatial variation within individual ingots.

Accordingly, what is needed is a radiation detector made from a compound, or alloy, which has excellent carrier transport properties and which fully depletes in response to an applied electric field. What is also needed is a method of forming such a compound, or alloy.

### SUMMARY OF THE INVENTION

The invention is a radiation detector made from a compound, or alloy, comprising: CdₓZn₁₋ₓTe, where 0≦x≦1; an element from column III or column VII of the periodic table in a concentration about 10 to 10,000 atomic parts per billion; and an element selected from the group consisting of La, Ce, Pr, Nd, Pm, Sm, Eu, Gd, Tb, Dy, Ho, Er, Tm, Yb and Lu in a concentration about 10 to 10,000 atomic parts per billion.

The invention is also a method of forming a radiation detector compound, or alloy, comprising: (a) providing a mixture of Cd, Zn and Te; (b) heating the mixture of Cd, Zn and Te to a liquid state; (c) adding to the liquid mixture a first dopant that adds shallow level donors, i.e., electrons, to the top of an energy band gap of said mixture when it is solidified; (d) adding to the liquid mixture a second dopant that adds deep level donors and/or acceptors to the middle of said band gap of said mixture when it is solidified; and (e) solidifying said mixture including said first and second dopants to form the compound, or alloy.

The first dopant is at least one element selected from one of column III or column VII of the periodic table. More specifically, the first dopant can be at least one element selected from the group consisting of B, Al, Ga, In, Tl, F, Cl, Br and I. The concentration of the first dopant in the compound, or alloy, can be about 10 to 10,000 atomic parts per billion.

The second dopant can be an element selected from the group consisting of La, Ce, Pr, Nd, Pm, Sm, Eu, Gd, Tb, Dy, Ho, Er, Tm, Yb and Lu having a concentration in the compound, or alloy, about 10 to 10,000 atomic parts per billion.

### BRIEF DESCRIPTION OF THE DRAWING

The single FIGURE is a perspective view of a portion of a crystal wafer including a plurality of picture elements or pixels formed into a pixilated array.

### DETAILED DESCRIPTION OF THE INVENTION

In accordance with the present invention, specific combinations of specific elements are introduced into CdₓZn₁₋ₓTe (0≦x≦1) in a controlled way in quantities appropriate to the growth method to reliably produce useful extrinsic or doped CdₓZn₁₋ₓTe (0≦x≦1) with high resistivity (semi-insulating) and excellent carrier transport properties that fully depletes under applied bias. In the method (referred to as “co-doping”), two different elements or dopants are incorporated to the CdₓZn₁₋ₓTe (0≦x≦1) crystals during the crystal growth process.

More specifically, a first dopant formed from an element from column III of the periodic table, namely, boron (B), aluminum (Al), gallium (Ga), indium (In), thallium (Tl), or column VII of the periodic table, namely, fluorine (F), chlorine (Cl), bromine (Br) or iodine (I) is introduced to CdₓZn₁₋ₓTe (0≦x≦1) in the 10 atomic parts per billion (ppb) to 10,000 atomic ppb concentration range (10-10,000 atomic ppb) along with a second dopant, formed from a rare earth element, such as lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) or lutetium (Lu) in about the 10 atomic ppb to 10,000 atomic ppb concentration range (10-10,000 atomic ppb). The resulting CdₓZn₁₋ₓTe (0≦x≦1) crystals are referred to as co-doped by X-Y, where X equals any of the elements B, Al, Ga, In, Tl, F, Cl, Br and I, and Y equals any of the elements La, Ce, Pr, Nd, Pm, Sm, Eu, Gd, Tb, Dy, Ho, Er, Tm, Yb, and Lu, i.e., co-doping by a Al—Er, In—Gd, Cl—Yb, etc.

The described co-doping technique works on the principle of electrical compensation. Intrinsic or undoped CdₓZn₁₋ₓTe (0≦x≦1) varies in resistivity due to doping by the uncontrolled amount of residual impurities and native defects such as cadmium vacancies, dislocations and an intrinsic deep level defect incorporated into the material during crystal growth. Some of these crystal defects are ionized at ambient temperature and provide an ample supply of free charge carriers, e.g., electrons or holes, resulting in conductive or low-resistivity CdₓZn₁₋ₓTe (0≦x≦1). The concentration of free charge carriers in these un-doped crystals is typically proportional to the concentration of the defects and their origins. These defects also trap charge carriers generated by external x-ray or gamma ray radiation thereby limiting their transport and the use of the material in radiation detector devices.

In intrinsic CdₓZn₁₋ₓTe (0≦x≦1), the concentration of cadmium vacancies, i.e., vacant lattice sites, are considered to be the dominant native defects that supply a high concentration of holes to the valance band of CdₓZn₁₋ₓTe (0≦x≦1) whereupon the compound or alloy is rendered P-type with a resistivity in the 10⁷ Ohm-cm range. This resistivity is at least three orders of magnitude lower than the maximum resistivity, 10¹⁰ Ohm-cm, achievable in this compound or alloy. Defects and impurities that produce free holes and electrons are referred to as acceptors and donors, respectively.

By the deliberate introduction of chosen elements that produce charge carriers of the opposite sign, the phenomenon of electrical compensation can be achieved. As a result, the concentration of free charge carriers can be made proportional to the difference of the concentrations of acceptor and donor defects. In CdₓZn₁₋ₓTe (0≦x≦1), the column III impurities (B, Al, Ga, In and Tl) or column VII impurities (F, Cl, Br and I) can serve as donors that compensate for the effect of acceptors such as cadmium vacancies. The net carrier concentration equals the difference in the concentration of the column III impurity or the column VII impurity and the concentration of the cadmium vacancies. In this method, the net carrier concentration is typically reduced by 2 to 6 orders of magnitude. It is, however, difficult to precisely and reliably control the exact concentration of acceptor and donor defects to achieve a fully compensated, i.e., high resistivity ≧10¹⁰ Ohm-cm, material. Typically, resistivity in the 10⁶-10⁹ Ohm-cm range is achieved by column III or column VII impurity doping in CdₓZn₁₋ₓTe (0≦x≦1). However, this process does not produce satisfactory radiation detector performance, which is associated with the presence of deep level intrinsic defects. The commercial success of radiation detectors is limited as high-efficiency, e.g., thicker than 1 mm, detectors cannot be fabricated from these crystals. By the introduction of carefully chosen doping elements in accordance with the present invention, these doping elements can complex with intrinsic deep level donors or acceptors whereupon the detrimental effect of the intrinsic defects can be reduced or eliminated.

In accordance with the present invention, a second dopant is introduced in addition to the first dopant formed from a column III or column VII impurity during the growth process of CdₓZn₁₋ₓTe (0≦x≦1) to achieve a material that has full electrical compensation, high-resistivity (semi-insulating), full depletion and excellent charge transport. By the introduction of the second dopant, i.e., La, Ce, Pr, Nd, Pm, Sm, Eu, Gd, Tb, Dy, Ho, Er, Tm, Yb or Lu, in combination with the first dopant formed from a column III or column VII element, the depletion properties of the detector as well as control of the electrical resistivity of CdₓZn₁₋ₓTe (0≦x≦1) material can be controlled and a fully compensated material obtained. With this method, semi-insulating CdₓZn₁₋ₓTe (0≦x≦1) with electrical resistivity exceeding 10¹⁰ Ohm-cm is reliably and reproducibly achieved. In this method, the second dopant electrically compensates the residual net charge carriers given by the difference of the concentrations of acceptors, i.e., cadmium vacancies, and donors, i.e., column III or column VII impurities. As a result, fully compensated CdₓZn₁₋ₓTe (0≦x≦1) with resistivity at or near the theoretical maximum value is reliably achieved.

In addition to electrically compensating the acceptors, i.e., cadmium vacancies, column III or column VII impurities also combine with cadmium vacancies to form impurity-vacancy pairs commonly known and referred to as A-centers. In this process, the energy level of the cadmium vacancy defect is shifted to the lower energy level of the A-center. The lower energy of the new defect, i.e., A-center, reduces the residency time of charge carriers or holes at the defect and improves the transport properties of carriers generated by external x-ray and gamma ray radiation. As a result, the performance of radiation detectors fabricated from the co-doped CdₓZn₁₋ₓTe (0≦x≦1) crystals is greatly improved.

The use of two dopants in parallel, i.e., co-doping, enables the use of low concentrations of individual dopants, or dopant elements, to achieve full compensation and excellent charge transport in CdₓZn₁₋ₓTe (0≦x≦1) crystals. This eliminates the adverse effects of commonly used single doping schemes on the carrier transport properties of CdₓZn₁₋ₓTe (0≦x≦1) through the use of massive concentrations of a compensating doping element. The high concentration of a dopant in a single dopant scheme masks the effects of the intrinsic deep level and does not passivate intrinsic deep level donors or acceptors thereby causing incomplete depletion of radiation detectors formed from CdₓZn₁₋ₓTe (0≦x≦1) doped with a single dopant, space charge build up during operation of the device and the collapse of the internal electric field in the radiation detector commonly known as polarization.

The co-doped semi-insulating CdₓZn₁₋ₓTe (0≦x≦1) crystals discussed above can be grown from, without limitation, melt by high-pressure Bridgman, vapor phase transport, gradient freeze, and electro-dynamic gradient.

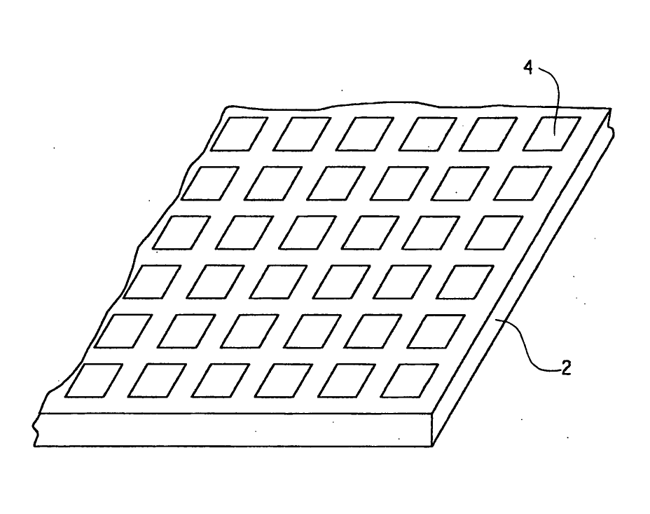

With reference to FIG. 1, once a CdₓZn₁₋ₓTe (0≦x≦1) crystal including the co-doping scheme discussed above has been formed into an ingot, a slice or wafer 2 of the crystal is removed therefrom. Wafer 2 can then be formed into a pixilated array where each picture element or pixel 4 is capable of converting incident radiation, such as x-rays and gamma rays, or incident particles, such as alpha or beta particles, into an electrical signal independent of every other pixel 4 of the array. Alternatively, wafer 2 can be a crystal that outputs an electrical signal in response to incident radiation or an incident particle, but which does not include a plurality of individual pixels 4. An example of wafer 2 including a single pixel 4 isolated from the reminder of wafer 2 is shown in FIG. 1. However, this is not to be construed as limiting the invention since a planar crystal can be formed in any desired and manufacturable size and shape.

The invention has been described with reference to the preferred embodiment. Obvious modifications and alterations will occur to others upon reading and understanding the preceding detailed description. It is intended that the invention be construed as including all such modifications and alterations insofar as they come within the scope of the appended claims or the equivalents thereof.

The invention is claimed to be:

1. A radiation detector made from a compound comprising: CdₓZn₁₋ₓTe, where 0≦x≦1; an element from column III or column VII of the periodic table in a concentration about 10 to 10,000 atomic parts per billion; and a rare earth element selected from the group consisting of La, Ce, Pr, Nd, Pm, Sm, Eu, Gd, Tb, Dy, Ho, Er, Tm, Yb and Lu in a concentration about 10 to 10,000 atomic parts per billion.

2. A method of forming a radiation detector compound comprising:
(a) providing a mixture of Cd, Zn and Te;
(b) heating the mixture to a liquid state;
(c) adding to the liquid mixture a first dopant that adds shallow level donors (electrons) to the top of an energy band gap of said mixture when it is solidified;
(d) adding to the liquid mixture a second dopant that adds deep level donors and/or acceptors to the middle of said band gap of said mixture when it is solidified; and
(e) solidifying said mixture including said first and second dopants to form the compound.

3. The method of claim 2, wherein the first dopant is an element from column III or column VII of the periodic table.

4. The method of claim 3, wherein the first dopant is an element selected from the group consisting of B, Al, Ga, In, Tl, F, Cl, Br and I.

5. The method of claim 2, wherein a concentration of the first dopant in the compound is about 10 to 10,000 atomic parts per billion.

6. The method of claim 2, wherein the second dopant is an element selected from the group consisting of La, Ce, Pr, Nd, Pm, Sm, Eu, Gd, Tb, Dy, Ho, Er, Tm, Yb and Lu.

7. The method of claim 2, wherein a concentration of the second dopant in the compound is about 10 to 10,000 atomic parts per billion.
